(19) United States
(12) Patent Application Publication
(10) Pub. No.: US 2010/0295569 A1
(43) Pub. Date: Nov. 25, 2010

(54) RF PERFORMANCE TEST STRUCTURE WITH ELECTRONIC SWITCH FUNCTION

(75) Inventors: CHIH-WEI CHU, Taipei (TW); Chia-Chun Fu, Taipei (TW)

Correspondence Address: KILE PARK GOEKJIAN REED & MCMANUS, 1200 NEW HAMPSHIRE AVE, NW, SUITE 570, WASHINGTON, DC, 20036, US

(73) Assignee: Azurewave Technologies, Inc.

(21) Appl. No.: 12/469,129

(22) Filed: May 20, 2009

(51) Int. Cl. G01R 29/08; G01R 1/067

(52) U.S. Cl. 324/754; 343/703

(57) ABSTRACT

An RF performance test structure is applied to test RF performance of an RF element via an RF measuring instrument. The RF performance test structure includes an antenna element, an RF test point and an electronic circuit switch chip. The RF test point connects to the RF measuring instrument. The electronic circuit switch chip has a first switch control input side, a second switch control input side, an RF signal input side connected to the RF element, a first RF signal output side connected to the antenna element, and a second RF signal output side connected to the RF test point. The first switch control input side and the second switch control input side respectively receive different signals in order to selectably transmit RF signals that are generated from the RF element and are received by the RF signal input side to the antenna element or the RF measuring instrument.

### BACKGROUND OF THE INVENTION

1. Field of the Invention

The present invention relates to an RF performance test structure, in particular, to an RF performance test structure with electronic switch function.

2. Description of Related Art

Due to the rapid development of wireless communication systems, wireless devices offering great convenience are widely used in daily communications. With wireless devices, people are able to exchange information, share experiences, and communicate with each other anytime and anywhere. Because of the wide usage of wireless devices, more various and new wireless products are developed.

To shorten the flow path of a new wireless product, before the production of the new wireless product, the manufacturer usually uses circuit simulation software to analyze the electrical characteristics of the new wireless product, and then estimates and improves the quality of the circuit of the new wireless product according to the result of the simulation. Usually a wireless device has two abilities: receiving radio signals and transmitting radio signals. To avoid wasting electric energy, when transmitting radio signals, an RF switch connector (radio frequency switch connector) is used to control operations of outputting the radio signals.

Although the RF switch connector is popular for testing the RF performance of the wireless product. However, it is a question of the price at first, the RF switch connector is about 0.1 US dollar, and the cost of the RF switch connector is expensive for manufacturer or designer. In addition, when the RF switch connector is disposed on a printed circuit board, the RF switch connector may occupy the usage space of the PCB. Hence, the size of the wireless product using the RF switch connector is difficult to reduce.

### SUMMARY OF THE INVENTION

In view of the aforementioned issues, the present invention provides an RF performance test structure with electronic switch function. The present invention is applied to test the RF performance of an RF element by using an electronic circuit switch chip to switch signal path in order to reduce cost and simplify test system.

To achieve the above-mentioned objectives, the present invention provides an RF performance test structure with electronic switch function for testing RF performance of an RF element via an RF measuring instrument. The RF performance test structure includes an antenna element, an RF test point and an electronic circuit switch chip. The RF test point is electrically connected to the RF measuring instrument. The electronic circuit switch chip has a first switch control input side, a second switch control input side, an RF signal input side electrically connected to the RF element, a first RF signal output side electrically connected to the antenna element, and a second RF signal output side electrically connected to the RF test point. The first switch control input side and the second switch control input side respectively receive different signals in order to selectably transmit RF signals that are generated from the RF element and are received by the RF signal input side to the antenna element or the RF measuring instrument.

To achieve the above-mentioned objectives, the present invention provides an RF performance test structure with electronic switch function for testing RF performance of an RF element via an RF measuring instrument. The RF performance test structure includes an antenna element, an RF test point and an electronic circuit switch chip. The RF test point is electrically connected to the RF measuring instrument. The electronic circuit switch chip is electrically connected to the RF element, the antenna element and the RF test point in order to selectably transmit RF signals that are generated from the RF element to the antenna element or the RF measuring instrument.

Therefore, the first switch control input side is electrically connected to a first signal, and the second switch control input side is electrically connected to a second signal. When user wants to normally use the RF element (the RF element mates with the antenna element), setting the first signal being larger than the second signal. Hence, the RF signals generated from the RF element are transmitted to the antenna element by switching the electronic circuit switch chip. When the RF element needs to be tested (the RF element is insulated from the antenna element), setting the first signal being smaller than the second signal. Hence, the RF signals generated from the RF element are transmitted to the RF measuring instrument by switching the electronic circuit switch chip.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1A is a function block of the RF performance test structure with electronic switch function to be used according to the first embodiment of the present invention;

FIG. 1B is a function block of the RF performance test structure with electronic switch function to be tested according to the first embodiment of the present invention;

FIG. 2 is a lateral, schematic view of the probe element of the RF performance test structure according to the present invention;

FIG. 3A is a function block of the RF performance test structure with electronic switch function to be used according to the second embodiment of the present invention; and

FIG. 3B is a function block of the RF performance test structure with electronic switch function to be tested according to the second embodiment of the present invention.

### DETAILED DESCRIPTION OF THE PREFERRED EMBODIMENTS

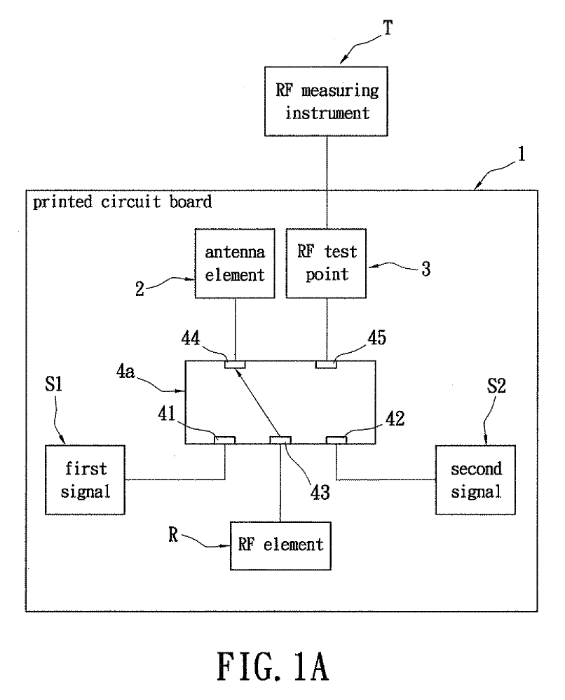

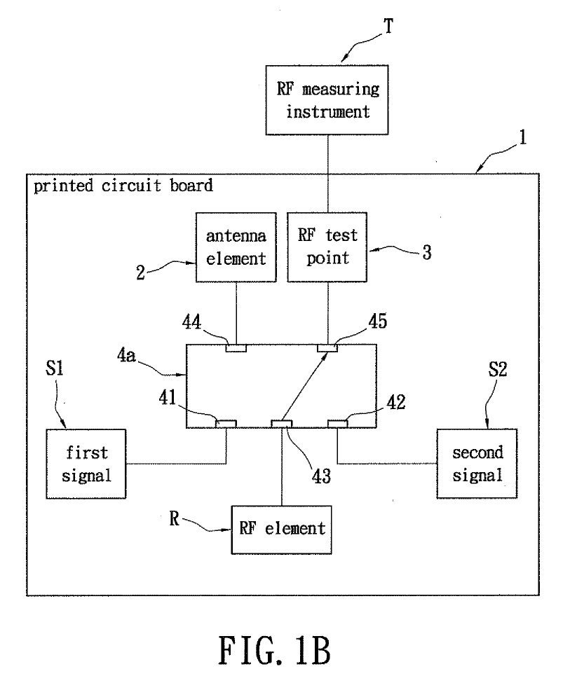

Referring to FIGS. 1A and 1B, the first embodiment of the present invention provides an RF (radio frequency) performance test structure with electronic switch function for testing RF performance of an RF element R via an RF measuring instrument T. The RF performance test structure includes a printed circuit board 1, an antenna element 2, an RF test point 3 and an electronic circuit switch chip 4a. The antenna element 2, the RF test point 3 and the electronic circuit switch chip 4a are electrically disposed on the printed circuit board 1.

The antenna element 2 can be an in-built antenna. The RF test point 3 is electrically connected to the RF measuring instrument T, and the antenna element 2 and the RF test point 3 are electrically connected to the electronic circuit switch chip 4a.

The electronic circuit switch chip 4a has a first switch control input side 41, a second switch control input side 42, an RF signal input side 43 electrically connected to the RF element R, a first RF signal output side 44 electrically connected to the antenna element 2, and a second RF signal output side 45 electrically connected to the RF test point 3. The first switch control input side 41 and the second switch control input side 42 are respectively receive different signals in order to selectably transmit RF signals that are generated from the RF element R and are received by the RF signal input side 43 to the antenna element 2 or the RF measuring instrument T.

For example, the first switch control input side 41 is electrically connected to a first signal S1, and the second switch control input side 42 is electrically connected to a second signal S2.

In the first embodiment, referring to FIG. 1A, when the first signal S1 is larger than the second signal S2 (for example, the first signal S1 is a predetermined voltage signal, and the second signal S2 is a grounding signal), the RF signals received by the RF signal input side 43 pass through the first RF signal output side 44 and transmit to the antenna element 2 (as the direction of the arrow shown in FIG. 1A).

In the first embodiment, referring to FIG. 1B, when the first signal S1 is smaller than the second signal 52 (for example, the first signal S1 is a grounding signal, and the second signal S2 is a predetermined voltage signal), the RF signals received by the RF signal input side 43 pass through the second RF signal output side 45 and transmit to the RF measuring instrument T.

In other words, when user wants to normally use the RF element R (the RF element R mates with the antenna element 2), setting the first signal S1 being larger than the second signal S2. Hence, the RF signals generated from the RF element R are transmitted to the antenna element 2 by switching the electronic circuit switch chip 4a (as shown in FIG. 1A). When the RF element R needs to be tested (the RF element R is insulated from the antenna element 2), setting the first signal S1 being smaller than the second signal S2. Hence, the RF signals generated from the RF element R are transmitted to the RF measuring instrument T by switching the electronic circuit switch chip 4a (as shown in FIG. 1B).

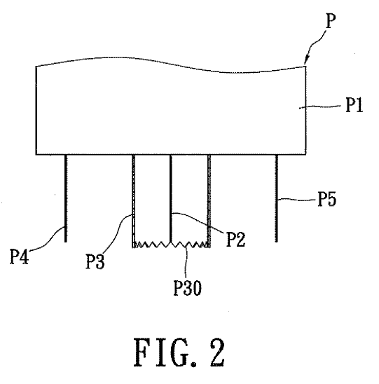

Referring to FIG. 2, the RF performance test structure further includes a probe element P electrically connected to the RF measuring instrument T. The probe element P has a probe body P1, an RF test pin P2 extending downwards from the probe body P1 and electrically connected to the RF test point 3, an annular claw structure P3 extending downwards from the probe body P2 and disposed around the RF test pin P2, a first signal input pin P4 extending downwards from the probe body P1 and electrically connected to the first switch control input side 41, and a second signal input pin P5 extending downwards from the probe body P1 and electrically connected to the second switch control input side 42.

Therefore, the RF test pin P2, the first signal input pin P4 and the second signal input pin P5 are respectively electrically connected to the RF test point 3, the first switch control input side 41 and the second switch control input side 42 by using the probe element P that is electrically connected to the RF measuring instrument T. Hence, when the signal outputted by the second signal input pin P5 is larger than the signal outputted by the first signal input pin P4 (the second signal input pin P5 outputs a predetermined voltage signal, and the first signal input pin P4 outputs a grounding signal), the RF signals generated from the RF element R are transmitted to the RF measuring instrument T by switching the electronic circuit switch chip 4a in order to test the RF performance of the RF element R.

In addition, the annular claw structure P3 has a plurality of thorns P30 disposed on a bottom side thereof for pressingly inserting into the RF test point 3 in order to fully enclose the RF test pin P2 in the annular claw structure P3. In other words, the RF test pin P2 is fully enclosed by matching the annular claw structure P3 with the RF test point 3. Hence, the RF signals outputted from the RF test point 3 can be fully received by the RF test pin P2 and the RF signals do not be leaked outside the annular claw structure P3.

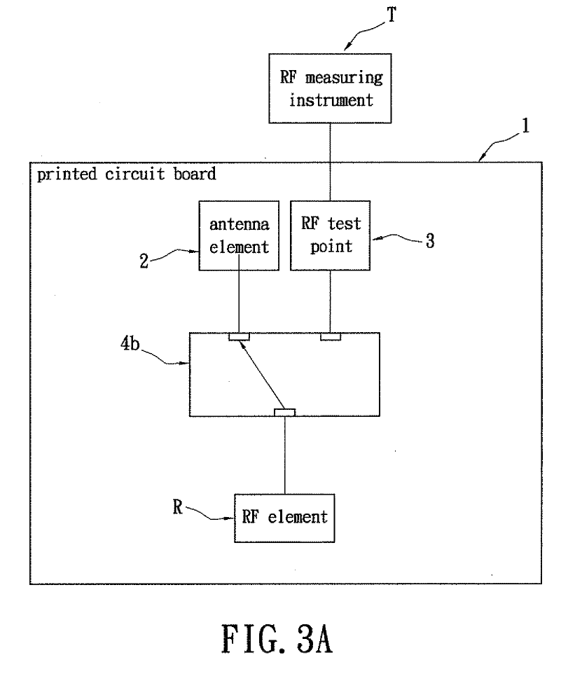

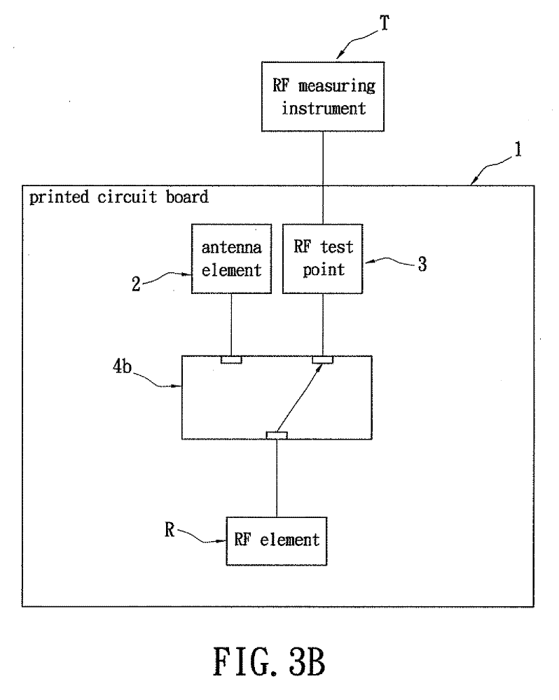

Referring to FIGS. 3A and 3B, the second embodiment of the present invention provides an RF (radio frequency) performance test structure with electronic switch function for testing RF performance of an RF element R via an RF measuring instrument T. The RF performance test structure includes a printed circuit board 1, an antenna element 2, an RF test point 3 and an electronic circuit switch chip 4b. The antenna element 2, the RF test point 3 and the electronic circuit switch chip 4b are electrically disposed on the printed circuit board 1.

Moreover, the difference between the second embodiment and the first embodiment is that: in the second embodiment, RF signals generated from the RF element R and received by the RF signal input side 43 can be selectably transmitted to the antenna element 2 or the RF measuring instrument T by any methods to switch the electronic circuit switch chip 4b. In other words, not only the electronic circuit switch chip 4b can be driven to switch signal path by signal drop (high signal and lower signal), but also the electronic circuit switch chip 4b can be driven to switch signal path by any methods according to different requirements.

In conclusion, the first switch control input side 41 is electrically connected to a first signal S1, and the second switch control input side 42 is electrically connected to a second signal S2. When user wants to normally use the RF element R (the RF element R mates with the antenna element 2), setting the first signal S1 being larger than the second signal S2. Hence, the RF signals generated from the RF element R are transmitted to the antenna element 2 by switching the electronic circuit switch chip 4a (as shown in FIG. 1A). When the RF element R needs to be tested (the RF element R is insulated from the antenna element 2), setting the first signal S1 being smaller than the second signal S2. Hence, the RF signals generated from the RF element R are transmitted to the RF measuring instrument T by switching the electronic circuit switch chip 4a (as shown in FIG. 1B).

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. An RF performance test structure with electronic switch function for testing RF performance of an RF element via an RF measuring instrument, the RF performance test structure comprising:
an antenna element;
an RF test point electrically connected to the RF measuring instrument; and
an electronic circuit switch chip having a first switch control input side, a second switch control input side, an RF signal input side electrically connected to the RF element, a first RF signal output side electrically connected to the antenna element, and a second RF signal output side electrically connected to the RF test point, wherein the first switch control input side and the second switch control input side respectively receive different signals in order to selectably transmit RF signals that are generated from the RF element and are received by the RF signal input side to the antenna element or the RF measuring instrument.

2. The RF performance test structure according to claim 1, further comprising a printed circuit board, wherein the antenna element, the RF test point and the electronic circuit switch chip are electrically disposed on the printed circuit board.

3. The RF performance test structure according to claim 1, wherein the antenna element is an in-built antenna.

4. The RF performance test structure according to claim 1, wherein the first switch control input side is electrically connected to a first signal, the second switch control input side is electrically connected to a second signal, and whereby when the first signal is larger than the second signal, the RF signals received by the RF signal input side pass through the first RF signal output side and transmit to the antenna element.

5. The RF performance test structure according to claim 4, wherein the first signal is a predetermined voltage signal, and the second signal is a grounding signal.

6. The RF performance test structure according to claim 1, wherein the first switch control input side is electrically connected to a first signal, the second switch control input side is electrically connected to a second signal and whereby when the first signal is smaller than the second signal, the RF signals received by the RF signal input side pass through the second RF signal output side and transmit to the RF measuring instrument.

7. The RF performance test structure according to claim 6, wherein the first signal is a grounding signal, and the second signal is a predetermined voltage signal.

8. The RF performance test structure according to claim 1, further comprising: a probe element electrically connected to the RF measuring instrument, wherein the probe element has a probe body, an RF test pin extending downwards from the probe body and electrically connected to the RF test point, an annular claw structure extending downwards from the probe body and disposed around the RF test pin, a first signal input pin extending downwards from the probe body and electrically connected to the first switch control input side, and a second signal input pin extending downwards from the probe body and electrically connected to the second switch control input side.

9. The RF performance test structure according to claim 8, wherein the annular claw structure has a plurality of thorns disposed on a bottom side thereof for pressingly inserting into the RF test point in order to fully enclose the RF test pin in the annular claw structure.

10. An RF performance test structure with electronic switch function for testing RF performance of an RF element via an RF measuring instrument, the RF performance test structure comprising:
an antenna element;
an RF test point electrically connected to the RF measuring instrument; and
an electronic circuit switch chip electrically connected to the RF element, the antenna element and the RF test point in order to selectably transmit RF signals that are generated from the RF element to the antenna element or the RF measuring instrument.

11. The RF performance test structure according to claim 10, further comprising a printed circuit board, wherein the antenna element, the RF test point and the electronic circuit switch chip are electrically disposed on the printed circuit board.

12. The RF performance test structure according to claim 10, wherein the antenna element is an in-built antenna.

13. The RF performance test structure according to claim 10, wherein the electronic circuit switch chip has a first switch control input side, a second switch control input side, an RF signal input side electrically connected to the RF element, a first RF signal output side electrically connected to the antenna element, and a second RF signal output side electrically connected to the RF test point.

14. The RF performance test structure according to claim 13, wherein the first switch control input side is electrically connected to a first signal, the second switch control input side is electrically connected to a second signal, and whereby when the first signal is larger than the second signal, the RF signals received by the RF signal input side pass through the first RF signal output side and transmit to the antenna element.

15. The RF performance test structure according to claim 14, wherein the first signal is a predetermined voltage signal, and the second signal is a grounding signal.

16. The RF performance test structure according to claim 13, wherein the first switch control input side is electrically connected to a first signal, the second switch control input side is electrically connected to a second signal, and whereby when the first signal is smaller than the second signal, the RF signals received by the RF signal input side pass through the second RF signal output side and transmit to the RF measuring instrument.

17. The RF performance test structure according to claim 16, wherein the first signal is a grounding signal, and the second signal is a predetermined voltage signal.

18. The RF performance test structure according to claim 13, further comprising: a probe element electrically connected to the RF measuring instrument, wherein the probe element has a probe body, an RF test pin extending downwards from the probe body and electrically connected to the RF test point, an annular claw structure extending downwards from the probe body and disposed around the RF test pin, a first signal input pin extending downwards from the probe body and electrically connected to the first switch control input side, and a second signal input pin extending downwards from the probe body and electrically connected to the second switch control input side.

19. The RF performance test structure according to claim 18, wherein the annular claw structure has a plurality of thorns disposed on a bottom side thereof for pressingly inserting into the RF test point in order to fully enclose the RF test pin in the annular claw structure.
